(19) United States
(12) Patent Application Publication
(10) Pub. No.: US 2026/0287664 A1
(43) Pub. Date: Sep. 24, 2026

(54) THERMAL BATTERY PARAMETER IDENTIFICATION

(71) Applicant: Raytheon Company, Tewksbury, MA (US)

(72) Inventor: Stephen John Fedigan, Marana, AZ (US)

(73) Assignee: Raytheon Company, Tewksbury, MA (US)

(21) Appl. No.: 19/087,941

(22) Filed: Mar. 24, 2025

(51) Int. Cl. G01R 31/389; G01R 31/3842

(52) U.S. Cl. CPC G01R 31/389; G01R 31/3842

(57) ABSTRACT

A power management unit architecture including multiple batteries in operative communication with an electrical load via a bus; a controller in operative communication with the batteries configured to perform steps for determining an impedance of at least one of the batteries, the set of instructions comprising: an instruction to apply at least one battery current pulse; an instruction to record a voltage waveform; an instruction to record a current waveform; an instruction to identify each of an open-circuit voltage, an equivalent series resistance, a double layer capacitance and a charge transfer resistance; an instruction for determining a state-of-power for at least one of the first battery, the second battery and the nth battery; and an instruction to switch from the first battery to the second battery and from the second battery to the nth battery.

### BACKGROUND

The present disclosure is directed to the improved battery staging system with the capacity to identify battery parameters to determine the battery state-of-power.

Certain critical power applications require an electrical power source capable of ultrahigh reliability and ultralow maintenance and virtually unlimited shelf life. In such batteries, the electrodes are fully assembled for operation, but the electrolyte is held in reserve in a separate container which may be within the battery container. Since there is no consumption of the electrodes under these circumstances, the shelf life of the battery is essentially indefinite. However, once the electrolyte is released from its reserve container, such as by mechanical puncture, explosive squib rupture or by any other means as are well known in the art, the battery is activated and thereafter has a limited standby life. Thermal batteries are useful for applications requiring extended storage time because they avoid deterioration of the active materials during storage and eliminate the loss of capacity due to self-discharge. A key feature is that the electrolyte is frozen at room temperature and is melted by the activation of heat pellets. Thermal batteries can have multiple chemistries. For example, a eutectic mixture of inorganic salts with inorganic binder can serve as the electrolyte between the anode and the cathode. A conductive heat source, consisting of iron and potassium perchlorate, is placed between each cell. When initiated, the heat pellets ignite, releasing heat and melting the eutectic electrolyte, producing voltage and current.

A thermal battery is totally inert and non-reactive until activated. Because most external environments have little or no effect on the inactivated battery, it can be stored for 20+ years. The battery can be activated at any time without preparation and will begin supplying power almost immediately. After activation, the battery quickly reaches peak voltage, which declines gradually during the rest of its active life as it cools to room temperature. Once activated, the battery functions until a critical active material is exhausted or until the battery cools below the electrolyte's melting point.

Initiating thermal batteries simultaneously constrains a mission for a limited duration of time to provide the necessary electrical power to the electrical loads. There are certain conditions and/or missions that require a longer period of battery power available.

Thermal batteries can be utilized in groups such that a first battery can be activated and at a future point in time, a subsequent battery can be activated to take on the load. However, the first battery being taken offline is susceptible to thermal runaway conditions if the power being produced is not properly managed. The offline battery can go into a thermal runaway condition and have venting problems unless a minimum current is drawn from the offline battery to a point in time when the voltage drops below a value of 10% of full voltage.

What is needed is a battery switchover topology that allows for sequential firing of thermal batteries extending available battery power.

### SUMMARY

In accordance with the present disclosure, there is provided a power management unit architecture comprising a first battery in operative communication with an electrical load via a bus; a second battery in operative communication with the electrical load via the bus and in operative communication with the first battery; an nth battery in operative communication with electrical load via the bus and in operative communication with an n−1th battery; a controller in operative communication with the first battery, the second battery and up to the nth battery, the controller comprising a computer readable storage device readable by the controller, tangibly embodying a program having a set of instructions executable by the controller to perform the following steps for determining an impedance of at least one of the first battery, the second battery and the nth battery, the set of instructions comprising: an instruction to apply at least one battery current pulse; an instruction to record a voltage waveform; an instruction to record a current waveform; an instruction to identify each of an open-circuit voltage, an equivalent series resistance, a double layer capacitance and a charge transfer resistance; an instruction for determining a state-of-power for at least one of the first battery, the second battery and the nth battery; and an instruction to switch from the first battery to the second battery and from the second battery to the nth battery.

A further embodiment of any of the foregoing embodiments may additionally and/or alternatively include the instruction to switch from the first battery to the second battery and from the second battery to the nth battery is responsive to a predetermined value of the battery state-of-power.

A further embodiment of any of the foregoing embodiments may additionally and/or alternatively include the instruction to record the current waveform and the instruction to record the voltage waveform is performed prior to applying the at least one battery current pulse.

A further embodiment of any of the foregoing embodiments may additionally and/or alternatively include the instruction to record the current waveform and the instruction to record the voltage waveform is performed during the application of the at least one battery current pulse.

A further embodiment of any of the foregoing embodiments may additionally and/or alternatively include the instruction to record the current waveform and the instruction to record the voltage waveform is performed after applying the at least one battery current pulse.

A further embodiment of any of the foregoing embodiments may additionally and/or alternatively include the instruction for determining a state-of-power for at least one of the first battery, the second battery and the nth battery comprises a voltage response to a leading edge of the at least one battery current pulse to compute an equivalent series resistance.

A further embodiment of any of the foregoing embodiments may additionally and/or alternatively include the instruction for determining a state-of-power for at least one of the first battery, the second battery and the nth battery comprises determining a voltage decay following the leading edge of the at least one battery current pulse to compute a charge transfer resistance.

A further embodiment of any of the foregoing embodiments may additionally and/or alternatively include the instruction for determining a state-of-power for at least one of the first battery, the second battery and the nth battery comprises a voltage recovery after a trailing edge of the at least one battery current pulse to calculate a time constant.

A further embodiment of any of the foregoing embodiments may additionally and/or alternatively include the first battery is a thermal battery, the second battery is a thermal battery, and the nth battery is a thermal battery.

In accordance with the present disclosure, there is provided a process for sequential activation of batteries connected to an electrical load comprising: operatively connecting a first battery with the electrical load; subsequently operatively connecting a second battery with the electrical load and operatively connecting the second battery in communication with the first battery; operatively connecting a controller in operative communication with the first battery and the second battery; applying at least one battery current pulse; recording a voltage waveform; recording a current waveform; identifying each of an open-circuit voltage, an equivalent series resistance, a double layer capacitance and a charge transfer resistance; determining a state-of-power for at least one of the first battery, the second battery and the nth battery; and switching from the first battery to the second battery and from the second battery to the nth battery.

A further embodiment of any of the foregoing embodiments may additionally and/or alternatively include switching from the first battery to the second battery and from the second battery to the nth battery is responsive to a predetermined value of the battery impedance.

A further embodiment of any of the foregoing embodiments may additionally and/or alternatively include the process further comprising recording the current waveform and recording the voltage waveform following the application of the at least one battery current pulse.

A further embodiment of any of the foregoing embodiments may additionally and/or alternatively include the process further comprising recording the current waveform and recording the voltage waveform during application of the at least one battery current pulse.

A further embodiment of any of the foregoing embodiments may additionally and/or alternatively include the process further comprising recording the current waveform and recording the voltage waveform after applying the at least one battery current pulse.

A further embodiment of any of the foregoing embodiments may additionally and/or alternatively include the process further comprising determining a state-of-power for at least one of the first battery, the second battery and the nth battery comprises determining a voltage response to a leading edge of the at least one battery current pulse to compute an equivalent series resistance.

A further embodiment of any of the foregoing embodiments may additionally and/or alternatively include the process further comprising determining a state-of-power for at least one of the first battery, the second battery and the nth battery comprises determining a voltage decay following the leading edge of the at least one battery current pulse to compute a charge transfer resistance.

A further embodiment of any of the foregoing embodiments may additionally and/or alternatively include the process further comprising determining a state-of-power for at least one of the first battery, the second battery and the nth battery comprises determining a voltage recovery after a trailing edge of the at least one battery current pulse to calculate a time constant.

A further embodiment of any of the foregoing embodiments may additionally and/or alternatively include the process further comprising determining an equivalent series resistance by taking several samples of a voltage and a current before and after a rising edge of the at least one battery current pulse.

A further embodiment of any of the foregoing embodiments may additionally and/or alternatively include the process further comprising determining differences between the voltage and current after the voltage and the current are averaged; and dividing the resulting voltage difference by the resulting current difference.

A further embodiment of any of the foregoing embodiments may additionally and/or alternatively include the first battery is a thermal battery, the second battery is a thermal battery, and the nth battery is a thermal battery.

Other details of the process are set forth in the following detailed description and the accompanying drawings wherein like reference numerals depict like elements.

### BRIEF DESCRIPTION OF THE DRAWINGS

The above and further advantages of this disclosure may be better understood by referring to the following description in conjunction with the accompanying drawings, in which like reference numerals indicate like elements and features in the various figures. Letters may be appended to reference numbers to distinguish from reference numbers for similar features and to indicate a correspondence to other features in the drawings. For clarity, not every element may be labeled in every figure. The drawings are not necessarily to scale, emphasis instead being placed upon illustrating the principles of the disclosure.

FIG. 1 is a schematic representation of an exemplary power management unit architecture.

FIG. 2 is a schematic representation of an exemplary battery circuit model.

FIG. 3 is a schematic representation of an exemplary graphic diagram representing an exemplary short duration current pulse and the battery's corresponding voltage response.

FIG. 4 is a schematic representation of an exemplary circuit for use with the current pulse.

### DETAILED DESCRIPTION

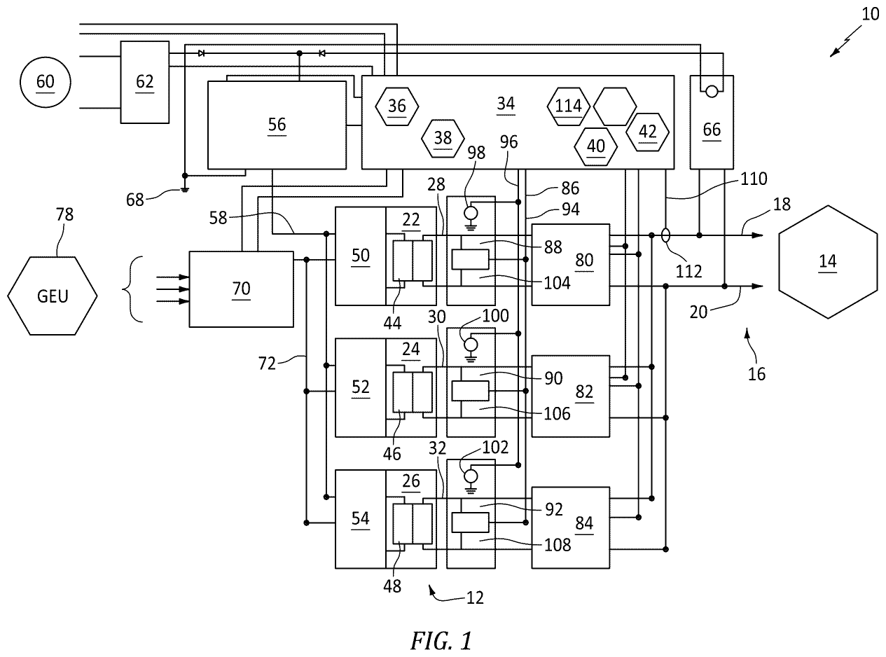

Referring now to FIG. 1, a power management unit architecture 10 is shown. A grouping of batteries 12 can be used to energize an electrical load 14. The electrical load 14 can be part of a missile, such as a control actuation system (not shown). The batteries 12 can be thermal batteries, lead acid batteries, Li-Ion and the like. The batteries 12 are connected to a bus 16 with a positive side 18 and a negative side 20. A first battery 22 is activated and connected to the electrical load 14 before a second battery 24 is activated and connected to the electrical load 14. Lastly, a third battery or nth battery 26 can be activated and connected to the electrical load 14 subsequently after the second battery 24. It is contemplated that any number of batteries 12 can be utilized depending on the mission and needs of the load 14. The bus 16 connects the batteries 12 to the load 14. The electrical load 14 can be supplied sequentially by a first battery current 28 from the first battery 22, and a second battery current 30 from the second battery 24, and an nth battery current 32 from the nth battery 26.

The power management unit architecture 10 includes the first battery 22 in operative communication with the electrical load 14. The second battery 24 can be in operative communication with the electrical load 14 and in operative communication with the first battery 22. The nth battery 26 can be in operative communication with the electrical load 14 and in operative communication with the first battery 22, the second battery 24 and up to an n−1th battery.

A digital signal processing system or simply controller 34 can be in operative communication with the first battery 22, the second battery 24 and all batteries up to the nth battery 26. The controller 34 can include hardware, firmware, and/or software components that are configured to perform the functions disclosed herein, including the functions of the power management unit architecture 10. While not specifically shown, the controller 34 may include other computing devices (e.g., servers, mobile computing devices, FPGAs, programmable logic devices, etc.) which may be in communication with each other and/or the controller 34 via a communication network 36 to perform one or more of the disclosed functions. The controller 34 may include at least one processor 38 (e.g., a controller, microprocessor, microcontroller, digital signal processor, etc.), memory 40, and an input/output (I/O) subsystem 42. The controller 34 may be embodied as any type of computing device e.g., a network of computers, a combination of computers and other electronic devices, or other electronic devices. Although not specifically shown, the I/O subsystem 42 typically includes, for example, an I/O controller, a memory controller, and one or more I/O ports. The processor 38 and the I/O subsystem 42 are communicatively coupled to the memory 40. The memory 40 may be embodied as any type of computer memory device (e.g., volatile memory such as various forms of random access memory).

The first battery 22 is the initial battery to be activated. At a predetermined state, the second battery 24 can be activated and up to the nth battery 26 can be activated in sequence. For a very brief period of time, both the first battery 22 and the second battery 24 are active and online with the load 14. The second battery 24 upon activation, goes online and picks up the load duty. The first battery 22 is taken offline. The power management unit architecture 10 is configured to prevent the offline first battery 22 from overheating and out-gassing during its offline stage, since the first battery 22 is still activated and has the potential to overheat. Periodically, the first battery current 28 is drawn off the first battery 22 and utilized either in the second battery 24 or on the load 14 or dumped as thermal energy or all of the above.

A first squib unit 44 is connected to the first battery. The first squib unit 44 is utilized to activate the first battery 22. A second squib unit 46 is connected to the second battery 24. An nth squib unit 48 is connected to the nth battery 26. In an exemplary embodiment, the squib unit 44, 46, 48 is a chemical that heats an electrolyte, producing voltage and current. In an exemplary embodiment, the squib unit 44, 46, 48 can include a bridge wire heating element that activates heat pellets, melts electrolyte which then produces voltage and current.

A first squib multiplexer (MUX) 50 is operatively connected to the first squib unit 44. A second squib multiplexer (MUX) 52 is operatively connected to the second squib unit 46. An nth squib multiplexer (MUX) 54 is operatively connected to the nth squib unit 46.

A squib driver circuit unit 56 is in operative communication with each of the squib units 44, 46, 48 via squib driver circuit 58. The squib driver circuit unit 56 is in operative communication with the controller 34. A squib power source 60 is operatively connected to the squib driver circuit unit 56 via a bus voltage sensor 62. The bus voltage sensor 62 is also in operative communication with the controller 34 and a DC-DC converter 66. The DC-DC converter 66 is connected to the bus 16. The squib driver circuit unit 56 and DC-DC converter 66 are in operative communication with ground 68.

A firing interlock logic unit 70 is operatively connected to the squib MUX 50, 52, 54 via a squib MUX control circuit 72. The firing interlock logic unit 70 is operatively connected to the controller 34 via fire command circuit 74 and bus sequence circuit 76. The firing interlock logic unit 70 can receive command inputs, such as pre-arm command, arm command and fire command from the guidance electronic unit (GEU) 78.

A first power switch 80 is in operative connection with the first battery 22, controller 34 and bus 16. A second power switch 82 is in operative connection with the second battery 24, controller 34 and bus 16. An nth power switch 84 is in operative connection with the nth battery, controller 34 and bus 16.

The power management unit architecture 10 includes a voltage sensing circuit 86 operatively connected between the controller 34 and the batteries 12. The voltage sensing circuit 86 can be operatively connected to a first voltage sensor 88 associated with the first battery 22. The voltage sensing circuit 86 can be operatively connected to a second voltage sensor 90 associated with the second battery 24. The voltage sensing circuit 86 can be operatively connected to an nth voltage sensor 92 associated with the nth battery 26. In an exemplary embodiment, the voltage sensors 88, 90, 92 can include a first resistor in series with a second resistor (not shown). The voltage sensing circuit 86 indicates a battery voltage 94.

The power management unit architecture 10 includes a temperature sensing circuit operatively connected between the controller 34 and the batteries 12. The temperature sensing circuit 96 can be operatively connected to a first temperature sensor 98 associated with the first battery 22. The temperature sensing circuit 96 can be operatively connected to a second temperature sensor 100 associated with the second battery 24. The temperature sensing circuit 96 can be operatively connected to an nth temperature sensor 102 associated with the nth battery 26.

A first telemetry unit 104 can be operatively connected to the first voltage sensor 88 and the first temperature sensor 98 and operatively connected to the first battery 22 and controller 34.

A second telemetry unit 106 can be operatively connected to the second voltage sensor 90 and the second temperature sensor 100 and operatively connected to the second battery 22 and controller 34.

An nth telemetry unit 108 can be operatively connected to the nth voltage sensor 92 and the nth temperature sensor 102 and operatively connected to the nth battery 22 and controller 34. The telemetry units 104, 106, 108 are configured for telemetry. Telemetry is an automated process used to collect measurements and other types of data remotely. The data is sent between devices and monitored for analysis to improve device performance.

A current sensing circuit 110 can be operatively connected between the controller 34 and a current sensor 112 in operative connection with the positive leg 18 of the bus 16. The current sensing circuit 52 can include a shunt circuit, a Hall circuit, a current transformer, and the like. The current sensing circuit 52 indicates the current between the bus 16 and the batteries 12.

The power switches 80, 82, 84 can enable a current path between an offline battery 22 and an online battery 24. The power switches 80, 82, 84 can be configured with a transistor, such as for example a power transistor, a Field Effect Transistor (FET), a Metal Oxide Semiconductor Field Effect Transistor (MOSFET), insulated-gate bipolar transistor (IGBT) and the like. The power switches 80, 82, 84 can be configured with a diode, such as a body diode. The power switches 80, 82, 84 can be coupled on the low side of the load 14. The power switches 80, 82, 84 can have the transistor connected to a ground (not shown). The power switches 80, 82, 84 can be in operative communication with an inductor (not shown). The controller 34 can operate the power switches 80, 82, 84 to alter the pathways for the current 28, 30, 32 to flow.

The power switches 80, 82, 84 can utilize silicon carbide technology to improve the packaging and the power density. The power switches 80, 82, 84 can be configured to be scaled. The power switches 80, 82, 84 can enable a path for reverse current into one of the batteries 12 during regeneration from the control actuation system (not shown).

The controller 34 can include an inner loop 114, the inner loop 114 can be configured to control the first battery current 28. The inner loop 114 can be configured to measure a loop error and apply one of a full voltage or no voltage for a predetermined period of time.

The controller 34 can include an outer loop 116. The outer loop 116 can be configured to control the battery 12 voltage.

The controller 34 is configured to transfer a charge from the first battery 22 to the second battery 24 when the first battery 22 is offline and the second battery 24 is online. The controller 34 is configured to measure a battery impedance. The controller 34 is configured to determine an online battery resistance responsive to each of a measurement of the online battery voltage when an inductor (not shown) is connected to the online battery and measurement of the online battery voltage when the inductor is disconnected from the online battery.

The power management unit architecture begins operation when the firing interlock logic 70 receives a battery firing pulse or firing command sequence from the GEU 78. Once the first battery 22 is fired, the on-board controller 34 collects voltage, current and temperature telemetry. Based on this data, the controller 34 assesses the state-of-charge (SOC) and impedance of the battery 22. If the battery 22 falls below a desired SOC or the battery 22 cannot deliver sufficient power to meet demands, the controller 34 automatically fires the next battery 24, using the operating battery 22 as a power source and an on-board squib driver 56. To conserve board real-estate, the squib driver 56 can be connected to any of the battery bridge wires thru a bank of load switches. After the battery 24 comes up to its desired voltage, the discharged battery 22 is taken offline and the new battery 24 is connected to the bus 16 thru a power switch topology. The offline battery 22 can be connected to a dissipation resistor to prevent thermal runaway. This process continues and ultimately employs the nth battery until the mission is completed.

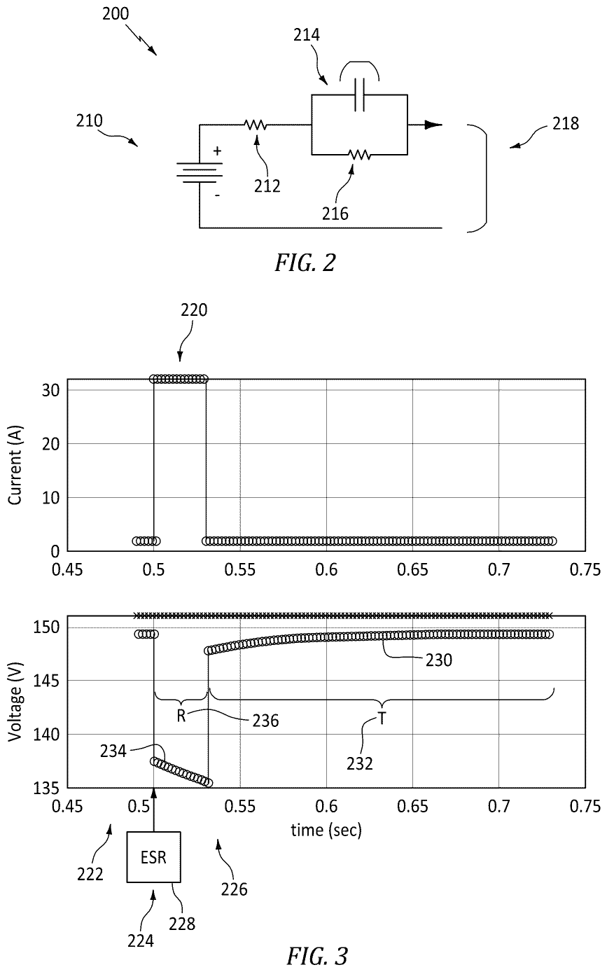

Referring also to FIG. 2, a diagram of an exemplary battery circuit model 200 is shown. The model 200 includes a battery 210 operatively coupled to a resistor RO 212 configured for determining an equivalent series resistance (ESR). The model 200 includes a capacitor 214 with associated dielectric double layer capacitance C. The model 200 includes a resistor 216 in parallel with capacitor 214, configured for determining a charge transfer resistance R. A load 218 is in operative communication with the battery 210.

To determine when to switch batteries 210, one should determine the impedance I of the battery 210. Determining the impedance I of the battery 210 can be based on equivalent circuit parameters such as, the battery's Open-Circuit Voltage (OCV), Equivalent Series Resistance (ESR), charge transfer resistance R, and dielectric capacitance C. These equivalent circuit parameters can change over time after the battery 210 is initiated due to the battery 210 cooling and due to changes in the battery's state-of-charge (SoC). The battery's Open-Circuit Voltage (OCV), Equivalent Series Resistance (ESR), charge transfer resistance R, and dielectric capacitance C can be utilized to determine the battery's State-of-Power (SoP).

It is desirable to limit the amount of power required to extract the equivalent circuit parameters, since using battery power to determine the equivalent circuit parameters can detract from the energy that would be used to power the load and will unnecessarily heat up the electronics in the power management unit 10. A passive method of determining the equivalent circuit parameters is ideal. However, during the cruise phase of a flight employing the battery 210, the load on the battery 210 may be quite small, making it highly difficult to estimate power consumption.

Referring also to FIG. 3, to keep the power consumption limited, a periodic, short duration current pulse 220 is applied to the battery circuit 200, so that the voltage and current waveforms can be recorded at different times, prior to the pulse 222, during the pulse 224, and after the pulse 226. The voltage response to the leading edge of the current pulse is used to compute Equivalent Series Resistance (ESR) 228. A voltage recovery 230 after the trailing edge of the current pulse 220 is for calculating a time constant 232, and the voltage decay 234 following the leading edge of the current pulse 220 is used to compute the charge transfer resistance R 236. Hardware is required to record and save voltage and current waveforms. Such hardware would include measurement circuits, filtering circuits and analog-to-digital converters.

The controller 34 can be employed to compute the variables for determining the State-of-Power. An algorithm within the controller 34 can be employed and utilize information prior to the battery current pulse and following the battery current pulse.

To compute the ESR 228, several samples of the voltage V and current A are taken before and after the rising edge of the current pulse 220. After these are averaged, the voltage and current differences are computed, and the resulting voltage difference is divided by the resulting current difference.

$${R}_{0} = ( {\overline{V}}_{POSTRISE} - {\overline{V}}_{PRERISE} ) / ( {\overline{I}}_{POSTRISE} - {\overline{I}}_{PRERISE} )$$

To compute the time constant 232, the voltage across the capacitor 214 following the trailing edge of the current pulse 220 is computed based on the decay formula:

$${V}_{C} = {V}_{C , PREFALL} {e}^{- ( \frac{{nT}_{s}}{τ} )} .$$

To compute V_{C}, the voltage measurements following the falling edge of the current pulse 220 are subtracted from the average pre-fall voltage, and the natural log is taken on both sides which results in:

$$ln ( {V}_{C} ) = ln ( {V}_{C , PREFALL} ) - \frac{t}{τ} ⇒ Δln ( {V}_{C} ) = - \frac{t}{τ}$$

Using a least-squares fit, the slope (and therefore time constant) is computed as:

$$- \frac{1}{τ} = \frac{\sum ( t Δln ( {V}_{C} ) )}{\sum {t}^{2}}$$

To compute the specific R and C values, the ESR voltage loss is subtracted from the terminal voltage to determine the drop across the RC parallel circuit:

$$ΔV = V - {R}_{0} I$$

This voltage difference is equal to current step response of the RC parallel circuit, which in the time domain is:

$$ΔV ( t ) = \frac{1}{C} {\int }_{0}^{t} {e}^{- ( \frac{t - σ}{τ} )} I ( σ ) d σ$$

$$t = Time from the rising current pulse edge$$

For constant pulse amplitude, the voltage output is:

$$ΔV ( t ) = R ( 1 - {e}^{- \frac{t}{τ}} ) I$$

In this equation, the voltage difference and current are measurements, time is known, and the time constant has already been estimated. For multiple data points, the equations can be written in matrix form as:

$$\{ \begin{matrix}{ΔV}_{1} \\ {ΔV}_{2} \\ ⋮\end{matrix} \} = R \{ \begin{matrix}{I}_{1} \cdot ( 1 - {e}^{- ( \frac{{t}_{1}}{τ} )} ) \\ {I}_{2} \cdot ( 1 - {e}^{- ( \frac{{t}_{2}}{τ} )} ) \\ ⋮\end{matrix} \} = R \{ \begin{matrix}{I}_{m 1} \\ {I}_{m 2} \\ ⋮\end{matrix} \}$$

Using least squares, the resistance is estimated as:

$$\hat{R} = ( {\sum }_{i = 1}^{n} {ΔV}_{i} {I}_{mi} ) / ( {\sum }_{i = 1}^{n} {I}_{mi}^{2} )$$

The parallel capacitance is then calculated as:

$$C = \frac{τ}{R}$$

A technical advantage of the disclosed battery staging system with the capacity to identify battery parameters to determine the battery state-of-power includes an applied battery pulse employed to identify open-circuit voltage, ESR, double layer capacitance, and charge transfer resistance. These four parameters provide better insight into a battery's state-of-power.

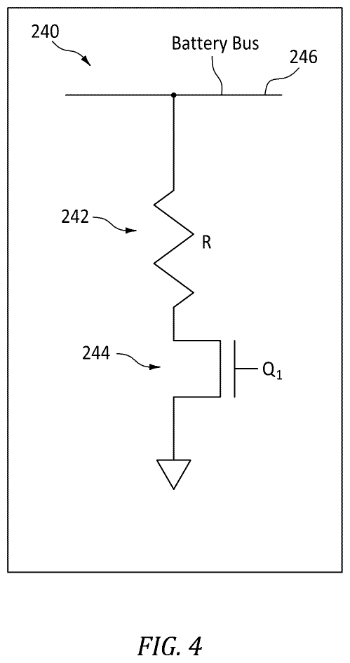

Referring also to FIG. 4, showing an exemplary circuit 240. The circuit 240 can include a resistor 242 in operative communication with a transistor Q₁ 244. The schematic shows the transistor 244 as an N-type MOSFET. However, the transistor 244 can be a P-type MOSFET, an NPN or PNP bi-polar junction transistor. The circuit 240 is in operative communication with a battery bus 246. The circuit 240 can be employed to generate the short duration current pulse 220. In this arrangement, it is possible for the load resistor to become hot and the current depends directly on the battery bus voltage. An alternative way to generate the current pulse 220 is by employing a simple control loop that measures the current and pulse-width modulates Q₁ to vary the voltage across the resistor. Current pulses can be applied throughout the lifetime of the active battery. The periodicity of those pulses can be fixed or can modulated in accordance with the rate of change in battery impedance.

Another technical advantage of the disclosed battery staging system with the capacity to identify battery parameters to determine the battery state-of-power includes employing an algorithm which is low complexity and can be easily implemented on a microprocessor in real-time.

Another technical advantage of the disclosed battery staging system with the capacity to identify battery parameters to determine the battery state-of-power includes employing the algorithm to utilize information prior to the battery current pulse and following the battery current pulse, thus the algorithm does not need to run continuously.

Another technical advantage of the disclosed battery staging system with the capacity to identify battery parameters to determine the battery state-of-power includes no current measurement being required to estimate the RC decay time.

There has been provided a battery staging system with the capacity to identify battery parameters to determine the battery state-of-power. While the battery staging system with the capacity to identify battery parameters to determine the battery state-of-power has been described in the context of specific embodiments thereof, other unforeseen alternatives, modifications, and variations may become apparent to those skilled in the art having read the foregoing description. Accordingly, it is intended to embrace those alternatives, modifications, and variations which fall within the broad scope of the appended claims.

What is claimed is:

1. A power management unit architecture comprising:
a first battery in operative communication with an electrical load via a bus;
a second battery in operative communication with the electrical load via the bus and in operative communication with the first battery;
an nth battery in operative communication with electrical load via the bus and in operative communication with an n−1th battery;
a controller in operative communication with the first battery, the second battery and up to the nth battery, the controller comprising a computer readable storage device readable by the controller, tangibly embodying a program having a set of instructions executable by the controller to perform the following steps for determining an impedance of at least one of the first battery, the second battery and the nth battery, the set of instructions comprising:
an instruction to apply at least one battery current pulse;
an instruction to record a voltage waveform;
an instruction to record a current waveform;
an instruction to identify each of an open-circuit voltage, an equivalent series resistance, a double layer capacitance and a charge transfer resistance;
an instruction for determining a state-of-power for at least one of the first battery, the second battery and the nth battery; and
an instruction to switch from the first battery to the second battery and from the second battery to the nth battery.

2. The power management unit architecture according to claim 1, wherein the instruction to switch from the first battery to the second battery and from the second battery to the nth battery is responsive to a predetermined value of the battery state-of-power.

3. The power management unit architecture according to claim 1, wherein the instruction to record the current waveform and the instruction to record the voltage waveform is performed prior to applying the at least one battery current pulse.

4. The power management unit architecture according to claim 1, wherein the instruction to record the current waveform and the instruction to record the voltage waveform is performed during the application of the at least one battery current pulse.

5. The power management unit architecture according to claim 1, wherein the instruction to record the current waveform and the instruction to record the voltage waveform is performed after applying the at least one battery current pulse.

6. The power management unit architecture according to claim 1, wherein the instruction for determining a state-of-power for at least one of the first battery, the second battery and the nth battery comprises a voltage response to a leading edge of the at least one battery current pulse to compute an equivalent series resistance.

7. The power management unit architecture according to claim 1, wherein the instruction for determining a state-of-power for at least one of the first battery, the second battery and the nth battery comprises determining a voltage decay following the leading edge of the at least one battery current pulse to compute a charge transfer resistance.

8. The power management unit architecture according to claim 1, wherein the instruction for determining a state-of-power for at least one of the first battery, the second battery and the nth battery comprises a voltage recovery after a trailing edge of the at least one battery current pulse to calculate a time constant.

9. The power management unit architecture according to claim 1, wherein the first battery is a thermal battery, the second battery is a thermal battery, and the nth battery is a thermal battery.

10. A process for sequential activation of batteries connected to an electrical load comprising:
operatively connecting a first battery with the electrical load;
subsequently operatively connecting a second battery with the electrical load and operatively connecting the second battery in communication with the first battery;
operatively connecting a controller in operative communication with the first battery and the second battery;
applying at least one battery current pulse;
recording a voltage waveform;
recording a current waveform;
identifying each of an open-circuit voltage, an equivalent series resistance, a double layer capacitance and a charge transfer resistance;
determining a state-of-power for at least one of the first battery, the second battery and the nth battery; and
switching from the first battery to the second battery and from the second battery to the nth battery.

11. The process according to claim 10, wherein switching from the first battery to the second battery and from the second battery to the nth battery is responsive to a predetermined value of the battery impedance.

12. The process according to claim 10, further comprising:
recording the current waveform and recording the voltage waveform following the application of the at least one battery current pulse.

13. The process according to claim 10, further comprising:
recording the current waveform and recording the voltage waveform during application of the at least one battery current pulse.

14. The process according to claim 10, further comprising:
recording the current waveform and recording the voltage waveform after applying the at least one battery current pulse.

15. The process of claim 10, further comprising:
determining a state-of-power for at least one of the first battery, the second battery and the nth battery comprises determining a voltage response to a leading edge of the at least one battery current pulse to compute an equivalent series resistance.

16. The process of claim 10, further comprising:
determining a state-of-power for at least one of the first battery, the second battery and the nth battery comprises determining a voltage decay following the leading edge of the at least one battery current pulse to compute a charge transfer resistance.

17. The process of claim 10, further comprising:
determining a state-of-power for at least one of the first battery, the second battery and the nth battery comprises determining a voltage recovery after a trailing edge of the at least one battery current pulse to calculate a time constant.

18. The process of claim 10, further comprising:
determining an equivalent series resistance by taking several samples of a voltage and a current before and after a rising edge of the at least one battery current pulse.

19. The process of claim 18, further comprising:
determining differences between the voltage and current after the voltage and the current are averaged; and
dividing the resulting voltage difference by the resulting current difference.

20. The process of claim 10, wherein the first battery is a thermal battery, the second battery is a thermal battery, and the nth battery is a thermal battery.
